(19) United States
(12) Patent Application Publication
(10) Pub. No.: US 2009/0230383 A1
(43) Pub. Date: Sep. 17, 2009

(54) Passive matrix organic light emitting diode display device

(75) Inventors: Hsin-Fei Meng, Hsinchu City (TW); Sheng-Fu Horng, Hsinchu City (TW); Yu-Chiang Chao, Bade City (TW)

Correspondence Address: Juan Carlos A. Marquez;c/o Stites & Harbison PLLC, 1199 North Fairfax Street, Suite 900, Alexandria, VA, 22314-1437, US

(73) Assignee: National Chiao Tung University

(21) Appl. No.: 12/153,233

(22) Filed: May 15, 2008

(30) Foreign Application Priority Data
Mar. 14, 2008 (TW) 097108980

(51) Int. Cl. H01L 51/52

(52) U.S. Cl. 257/40; 313/504; 257/E51.019

(57) ABSTRACT

A passive matrix organic light emitting diode display device comprises a plurality of vertical organic light emitting transistors, each having a first collector, a first grid/base, and a first emitter. Therein, the first collectors are electrically connected and arranged parallelly to form a plurality of first scan units, and the first grids/bases are electrically connected and arranged parallelly to form a plurality of second scan units, while the first emitters are integrated into a common electrode, in which the first scan units and the second scan units are perpendicularly crossed. By perpendicularly combining vertical transistors onto organic light emitting diodes so as to drive the organic light emitting diodes, an active area as well as a luminance of the organic light emitting diode display device are enhanced and consequently an aperture ratio of each pixel unit in the organic light emitting diode display device is increased.

### BACKGROUND OF THE INVENTION

1. Technical Field

The present invention relates to passive matrix organic light emitting diode (PMOLED) display devices. More particularly, the present invention relates a PMOLED display device constructed of a matrix of vertical organic light emitting transistors.

2. Description of Related Art

As one of the most promising flat panel display devices of nowadays, the organic light emitting diode (OLED) display device adopts a light emitting principle different from that of the prior liquid crystal display device, which uses liquid crystals as an optical switching medium. That is because of that liquid crystals do not naturally emit light and thus need a backlight source and an external electric voltage applied thereon to rotate the liquid crystals and manage the light transmission rate of the backlight source. Differently, the organic light emitting diodes emit light when receiving an electric current and need no additional backlight source, thereby bringing advantages of a light weight and a compact size to a display device using the same.

FIG. 1 is a diagram of an equivalent circuit of a circuit of a conventional PMOLED (Passive Matrix Organic Light Emitting Diode) display device and FIG. 2 is a diagram of the circuit of the conventional PMOLED display device.

As shown in FIG. 1, the equivalent circuit of the circuit of the conventional PMOLED display device comprises a plurality of first transistors (T_{S11}˜T_{S1m}, T_{S21}˜T_{S2m}, . . . , T_{Sn1}˜T_{Snm}), a plurality of second transistors (T_{D11}˜T_{D1m}, T_{D21}˜T_{D2m}, . . . , T_{Dn1}˜T_{Dnm}) and a plurality of organic light emitting diodes 11.

Conventionally, the PMOLED display device implements a circuit wiring manner similar to that used in an LCD device, wherein data signal lines (D1, D2, . . . , Dm) and scan signal lines (S1, S2, . . . , Sn) are perpendicularly crossed and each set of a said data signal line and a said scan signal line that are crossed controls a pixel unit 12 that comprises one said first transistor T_{S11}, one said second transistor T_{D11}, and one said organic light emitting diode 11.

For example, the first transistor T_{S11}, having a gate that is electrically connected to the scan signal line S1 and a source that is electrically connected to the data signal line D1, acts as a storage switch for addressably storing input image data. The second transistor T_{D11} has a gate that is electrically connected to a drain of the first transistor T_{S11} and a source that is electrically connected to a power supply voltage V_{DD}. The organic light emitting diode 11 has an anode that is electrically connected to a drain of the second transistor T_{D11} and a cathode electrically connected to a ground potential GND. Thereby, each said pixel unit 12 can be turned on/off by using a data driver 13 and a gate driver 14 to control the data signal lines (D1, D2, . . . , Dm) and the scan signal lines (S1, S2, . . . , Sn), respectively.

However, as can be seen in FIG. 2, the first transistors (T_{S11}˜T_{S1m}, T_{S21}˜T_{S2m}, . . . , T_{Sn1}˜T_{Snm}) and the second transistors (T_{D11}˜T_{D1m}, T_{D21}˜T_{D2m}, . . . , T_{Dn1}˜T_{Dnm}) take a substantial area on the OLED display device, and consequently decrease an aperture ratio of each said pixel unit 12 that in turn reduce an active area of the pixel unit 12. To state briefly, the conventional organic light emitting diode display device suffers a limitation in image definition thereof due to the presence of the first transistors (T_{S11}˜T_{S1m}, T_{S21}˜T_{S2m}, . . . , T_{Sn1}˜T_{Snm}) and the second transistors (T_{D11}˜T_{D1m}, T_{D21}˜T_{D2m}, . . . , T_{Dn1}˜T_{Dnm}).

### SUMMARY OF THE INVENTION

The present invention provides a passive matrix organic light emitting diode display device, which is composed of a plurality of vertical organic light emitting transistors. Since the vertical organic light emitting transistor is constructed by vertically integrating a transistor with an organic light emitting diode, it takes a reduced area on the organic light emitting diode display device, so as to improve an aperture ratio of each pixel unit and in turn enhance an overall active area as well as a luminance of the organic light emitting diode display device.

To achieve the aforementioned objective, the disclosed passive matrix organic light emitting diode display device comprises a plurality of vertical organic light emitting transistors, each having a first collector, a first grid/base, and a first emitter, wherein the first collectors are electrically connected and arranged parallelly to form a plurality of first scan units, and the first grids/bases are electrically connected and arranged parallelly to form a plurality of second scan units while the first emitters are electrically connected and arranged parallelly to form a plurality of third scan units, in which the first scan units and the second scan units are crisscrossed while the second scan units and the third scan units are crisscrossed.

By implementing the present invention, at least the following progressive effects can be achieved:
1. By using vertical organic light emitting transistors to construct a passive matrix organic light emitting diode display device, an aperture ratio at each pixel unit is increased.
2. An overall active area and a luminance of a passive matrix organic light emitting diode display device are enhanced.
3. An image definition of a passive matrix organic light emitting diode display device is advanced.

### BRIEF DESCRIPTION OF THE DRAWINGS

The invention as well as a preferred mode of use, further objectives and advantages thereof, will best be understood by reference to the following detailed description of an illustrative embodiment when read in conjunction with the accompanying drawings, wherein:

FIG. 1 is a diagram of an equivalent circuit of a circuit of a conventional passive matrix organic light emitting diode display device;

FIG. 2 is a diagram of the circuit of the conventional passive matrix organic light emitting diode display device;

FIG. 3 is a perspective view of a passive matrix organic light emitting diode display device according to a first embodiment of the present invention;

FIG. 4 is a top view of the passive matrix organic light emitting diode display device according to the first embodiment of the present invention;

FIG. 5 is a perspective view of a passive matrix organic light emitting diode display device according to a second embodiment of the present invention;

FIG. 6 is a sectional view taken in row A-A of FIG. 3 according to a first aspect of the present invention;

FIG. 7 is a sectional view taken in row A-A of FIG. 3 according to a second aspect of the present invention;

FIG. 8 is a sectional view taken in row A-A of FIG. 3 according to a third aspect of the present invention;

FIG. 9 is a sectional view taken in row A-A of FIG. 3 according to a fourth aspect of the present invention; and

FIG. 10 is a sectional view taken in row A-A of FIG. 3 according to a fifth aspect of the present invention.

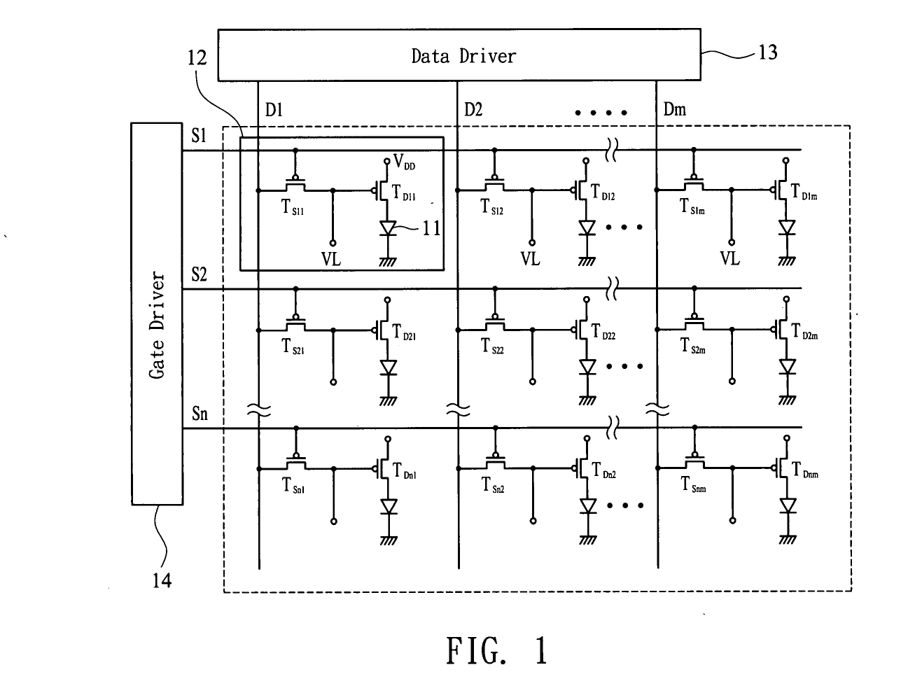

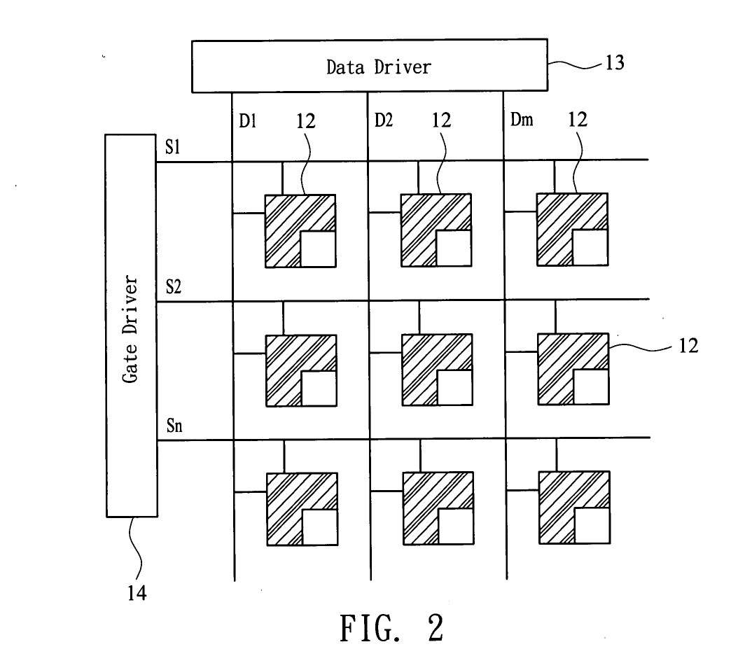

### DETAILED DESCRIPTION OF THE PREFERRED EMBODIMENT

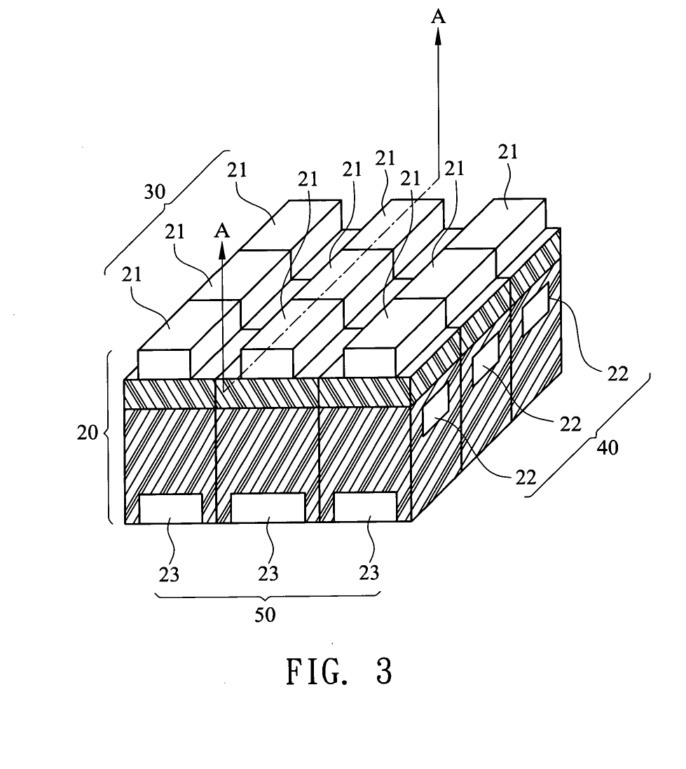

As illustrated in FIG. 3, a passive matrix organic light emitting diode display device according to a first embodiment of the present invention comprises a plurality of vertical organic light emitting transistors 20, each having a first collector 21, a first grid/base 22, and a first emitter 23. Therein, the plural vertical organic light emitting transistors 20 are crisscrossed into a matrix. As shown in FIG. 3, the display device comprises a matrix constructed from 3×3 vertical organic light emitting transistors 20.

The first collectors 21 of the vertical organic light emitting transistors 20 placed in a same column are electrically connected to form a plurality of first scan units 30 that are mutually parallel. The first grids 22 or the first bases 22 of the vertical organic light emitting transistors 20 placed in a same row are electrically connected to form a plurality of second scan units 40 that are mutually parallel. Similarly, the first emitters 23 of the vertical organic light emitting transistors 20 placed in a same column are electrically connected to form a plurality of third scan units 50 that are mutually parallel.

With reference to FIG. 4, the first scan units 30 are mutually parallel while being crisscrossed with the second scan units 40. Similarly, the third scan units 50 are crisscrossed with the second scan units 40. That is to say, the third scan units 50 and the first scan units 30 are mutually parallel so as to construct the passive matrix organic light emitting diode display device. In addition, an external circuit may be implemented to control the first scan units 30, the second scan units 40 and the third scan units 50, thereby driving each said vertical organic light emitting transistor 20.

For example, by conducting the first scan units 30 and the third scan units 50 of the first column plus the second scan units 40 of a second row, the vertical organic light emitting transistor 20 located at an intersection of the second row and the first column can be driven. Or, by conducting the first scan units 30 and the third scan units 50 of the second and third columns plus the second scan units 40 of the first row, the vertical organic light emitting transistor 20 located at an intersection of the second row and the second column and another said vertical organic light emitting transistor 20 located at an intersection of the first row and the third column can be driven at the same time. Consequently, each said vertical organic light emitting transistor 20 can be controlled respectively through the external circuit.

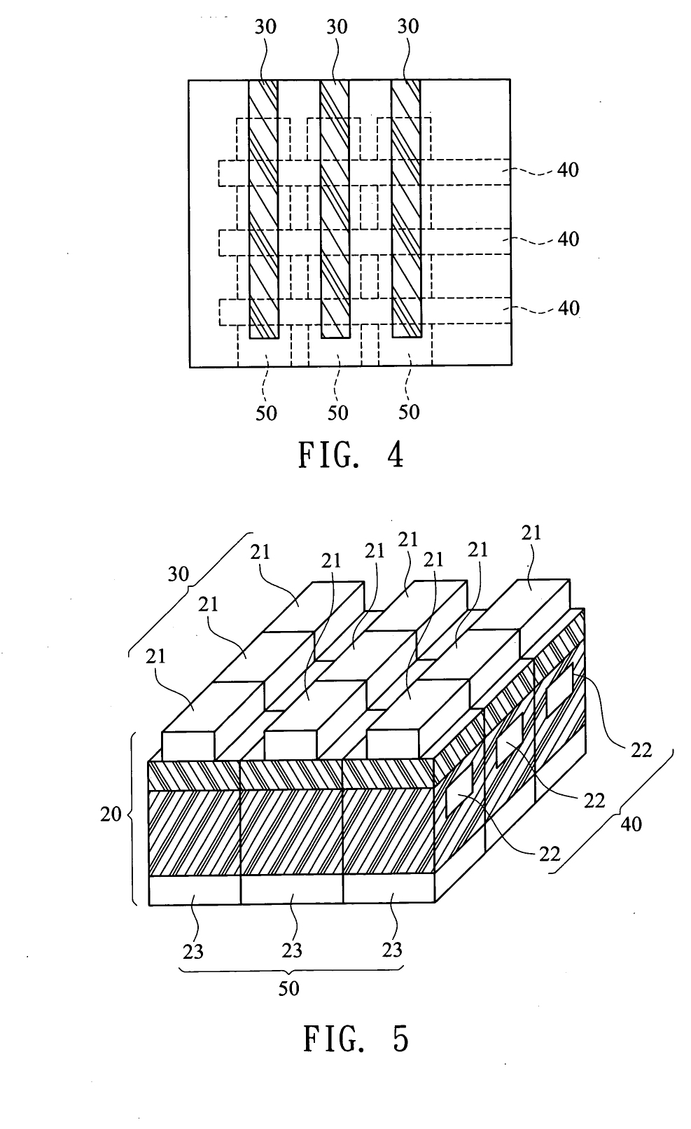

As shown in FIG. 5, the third scan units 50 may be integrated as a common electrode so that when the third scan units 50 are conducted, the vertical organic light emitting transistor 20 can be selectively driven by controlling the first scan units 30 and the second scan units 40. For example, the first scan units 30 of the first column and the second scan units 40 of the second row can be conducted to drive the vertical organic light emitting transistor 20 located at an intersection of the second row and the first column. Or, by conducting the first scan units 30 of the second column and the third column plus the second scan units 40 of the first row, the vertical organic light emitting transistors 20 located at an intersection of the second row and the second column as well as another said vertical organic light emitting transistors 20 located at an intersection of the first row and the third column can be driven.

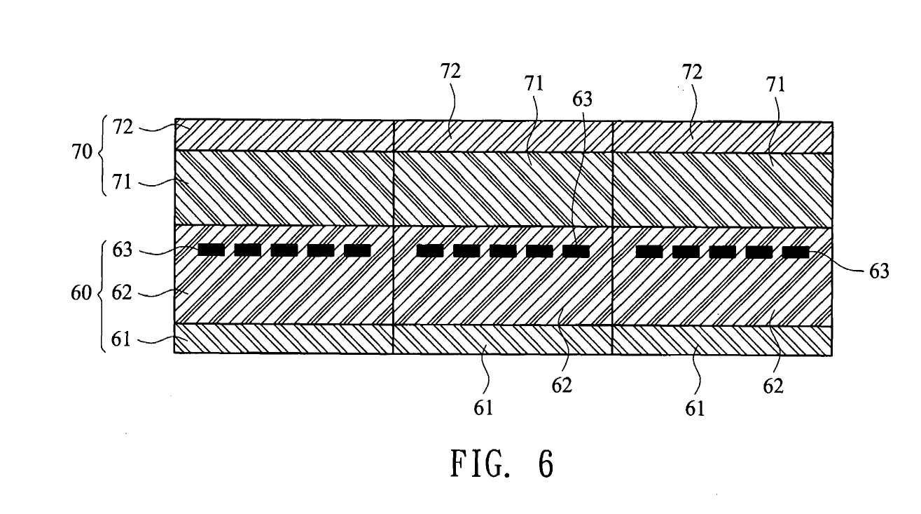

FIG. 6 provides a sectional view of the passive matrix organic light emitting diode display device according to a first aspect of the present invention. Therein, each said vertical organic light emitting transistor 20 further comprises a first vertical transistor 60 and a first organic light emitting diode 70.

The first vertical transistor 60 comprises a first electrode 61, a first organic layer 62, and a second electrode 63. The first organic layer 62 is stacked on the first electrode 61 and the second electrode 63 is located in the first organic layer 62. The second electrode 63 may be located in any portion of the first organic layer 62, including being settled on the first organic layer 62. The second electrode 63 controls an amount of electrons/electron holes pass therethrough so as to modulate the luminance of the first organic light emitting diode 70.

The first organic layer 62 may be selected from a group consisting of an HIL (Hole Injection Layer), an HTL (Hole Transport Layer), an HBL (Hole Blocking Layer), an EBL (Electron Blocking Layer), an ETL (Electron Transport Layer) and an EIL (Electron Injection Layer).

The first organic light emitting diode 70 comprises a second organic layer 71 and a third electrode 72. The second organic layer 71 comprises an EML (EMission Layer), or further comprises one layer selected from a group consisting of an HIL, an HTL, an HBL, an EBL, an ETL and an EIL so as to reduce energy barrier difference between the layers and in turn enhance luminescence efficiency of the first organic light emitting diode 70. The second organic layer 71 is perpendicularly stacked on the first vertical transistor 60, for example, on the first organic layer 62 or the second electrode 63 while the third electrode 72 is stacked on the second organic layer 71.

The first electrode 61 of the first vertical transistor 60 may be an anode, and may act as the first emitter 23 of the vertical organic light emitting transistor 20. The first electrode 61 may be a transparent electrode such as ITO (Indium Tin Oxide), or may be made of gold, platinum, molybdenum oxide/aluminum, PEDOT/molybdenum oxide/aluminum, or a combination thereof. The first organic layer 62 may comprises an HIL and an HTL, wherein the HIL may be stacked on the first electrode 61 and the HTL may be then stacked on the HIL.

The second electrode 63 of the first vertical transistor 60 may be a grid and may act as the first grid 22 of the vertical organic light emitting transistor 20. The second electrode 63 may be located in any portion of the HTL, including being settled on the HTL. The third electrode 72 of the first organic light emitting diode 70 may be a cathode for acting as the first collector 21 of the vertical organic light emitting transistor 20. The third electrode 72 may be made of calcium/aluminum, lithium fluoride/aluminum, cesium fluoride/aluminum, barium/aluminum, or a combination thereof.

The second electrode 63 of the first vertical transistor 60 serves to control an amount of the electron holes entering the first organic light emitting diode 70. The electron holes are allowed to pass the second electrode 63 and enter the first organic light emitting diode 70 by properly modulating voltages of the second electrode 63 and the third electrode 72. After entering the first organic light emitting diode 70, the electron holes are recombined with the electrons injected from the third electrode 72 at the second organic layer 71 and thereby the EML of the second organic layer 71 emits light.

Besides, the first electrode 61 of the first vertical transistor 60 may be also a cathode for acting as the first emitter 23 of the vertical organic light emitting transistor 20. The first electrode 61 may be made of calcium/aluminum, lithium fluoride/aluminum, cesium fluoride/aluminum, barium/aluminum, or a combination thereof. The first organic layer 62 may comprise an ETL that is stacked on the first electrode 61. The second electrode 63 of the first vertical transistor 60 may be a grid for acting as the first grid 22 of the vertical organic light emitting transistor 20 and may be located in any portion of the ETL, including being settled on the ETL. The third electrode 72 of the first organic light emitting diode 70 may be an anode and may act as the first collector 21 of the vertical organic light emitting transistor 20. The third electrode 72 may be a transparent electrode such as ITO (Indium Tin Oxide) so that the light emitted from the first organic light emitting diode 70 is allowed to pass through the third electrode 72 and emit upward. Alternatively, the third electrode 72 may be made of gold, platinum, molybdenum oxide/aluminum, PEDOT/molybdenum oxide/aluminum, or a combination thereof.

The second electrode 63 serves to control an amount of the electrons entering the first organic light emitting diode 70. The electrons are allowed to pass the second electrode 63 and enter the first organic light emitting diode 70 by properly modulating voltages of the second electrode 63 and the third electrode 72. After entering the first organic light emitting diode 70, the electrons are recombined with the electron holes injected from the third electrode 72 at the second organic layer 71 and thereby the EML of the second organic layer 71 emits light.

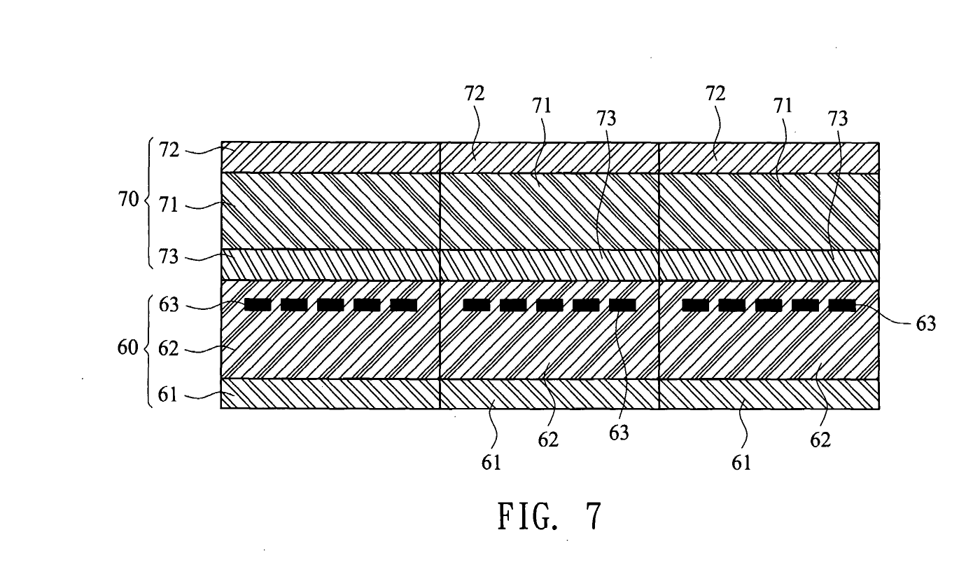

FIG. 7 provides a sectional view of the passive matrix organic light emitting diode display device according to a second aspect of the present invention. In this aspect, a fourth electrode 73 is additionally provided between the first organic layer 62 of the first vertical transistor 60 and the second organic layer 71 of the first organic light emitting diode 70 of FIG. 6. The fourth electrode 73 may be made of a metal, such as aluminum or silver, or the fourth electrode 73 may be formed as a multi-layer structure comprising a highly conductive macromolecular material such as PEDOT or a metal and other materials. Such multi-layer structure may be made of aluminum/molybdenum oxide, aluminum/molybdenum oxide/PEDOT, gold/PEDOT and so on.

As mentioned previously, when the first electrode 61 of the first vertical transistor 60 is the anode acting as the first emitter 23 of the vertical organic light emitting transistor 20, and the second electrode 63 of the first vertical transistor 60 is the grid acting as the first grid 22 of the vertical organic light emitting transistor 20 while the third electrode 72 of the first organic light emitting diode 70 is the cathode acting as the first collector 21 of the vertical organic light emitting transistor 20, the fourth electrode 73 is properly an anode.

Otherwise, when the first electrode 61 of the first vertical transistor 60 is the cathode acting as the first emitter 23 of the vertical organic light emitting transistor 20, and the second electrode 63 of the first vertical transistor 60 is the grid acting as the first grid 22 of the vertical organic light emitting transistor 20 while the third electrode 72 of the first organic light emitting diode 70 is the anode acting as the first collector 21 of the vertical organic light emitting transistor 20, the fourth electrode 73 is properly a cathode.

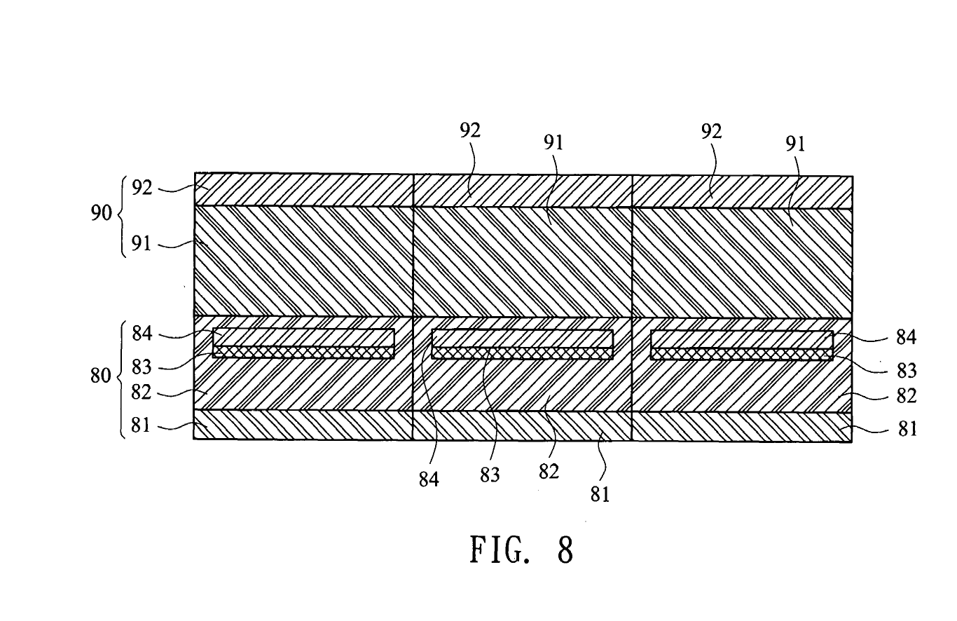

In FIG. 8, a sectional view of the passive matrix organic light emitting diode display device according to a third aspect of the present invention is provided. Therein, each said vertical organic light emitting transistor 20 comprises a second vertical transistor 80 and a second organic light emitting diode 90.

The second vertical transistor 80 comprises a fifth electrode 81, a third organic layer 82, an insulation layer 83, and a sixth electrode 84. The third organic layer 82 is stacked on the fifth electrode 81 while the insulation layer 83 is sandwiched between the third organic layer 82 and the sixth electrode 84. The third organic layer 82 may be selected from a group consisting of an HIL (Hole Injection Layer), an HTL (Hole Transport Layer), an HBL (Hole Blocking Layer), an EBL (Electron Blocking Layer), an ETL (Electron Transport Layer) and an EIL (Electron Injection Layer).

The second organic light emitting diode 90 comprises a fourth organic layer 91 and a seventh electrode 92. The fourth organic layer 91 comprises an EML (EMission Layer), or further comprises one layer selected from a group consisting of an HIL, an HTL, an HBL, an EBL, an ETL and an EIL so as to reduce energy barrier difference between the layers by different combinations and in turn enhance luminescence efficiency of the second organic light emitting diode 90. The fourth organic layer 91 is perpendicularly stacked on the second vertical transistor 80, for example, perpendicularly stacked on the sixth electrode 84 while the seventh electrode 92 is stacked on the fourth organic layer 91.

The fifth electrode 81 of the second vertical transistor 80 may be an anode, and may act as the first emitter 23 of the vertical organic light emitting transistor 20. The fifth electrode 81 may be a transparent electrode such as ITO (Indium Tin Oxide), or may be made of gold, platinum, molybdenum oxide/aluminum, PEDOT/molybdenum oxide/aluminum, or a combination thereof. The third organic layer 82 may comprise an HIL and an HTL, wherein the HIL may be stacked on the fifth electrode 81 and the HTL may be then stacked on the HIL. The insulation layer 83 may be first stacked on the HTL, and then the sixth electrode 84 may be stacked on the insulation layer 83. The sixth electrode 84 may be a base for acting as the first base 22 of the vertical organic light emitting transistor 20. The fourth organic layer 91 of the second organic light emitting diode 90 may comprise an EML (EMission Layer), and the seventh electrode 92 may be a cathode for acting as the first collector 21 of the vertical organic light emitting transistor 20, wherein the seventh electrode 92 may be made of calcium/aluminum, lithium fluoride/aluminum, cesium fluoride/aluminum, barium/aluminum, or a combination thereof.

When the insulation layer 83 and the sixth electrode 84 are in proper thicknesses, the electron holes injected from the fifth electrode 81 are allowed to tunnel through the insulation layer 83 and then pass through the sixth electrode 84 ballistically. By controlling the current of the sixth electrode 84, the electron holes can pass the sixth electrode 84 and get into the fourth organic layer 91 without collision and contribute to the base current. After passing through the sixth electrode 84 and reaching the fourth organic layer 91, the electron holes are recombined with the electrons injected from the seventh electrode 92 at the fourth organic layer 91 and thereby the light emits from the EML of the fourth organic layer 91. Consequently, a light-emitting intensity of the second organic light emitting diode 90 can be controlled by using a current of the sixth electrode 84 to modulate the amount the electron holes entering the second organic light emitting diode 90.

Besides, the fifth electrode 81 of the second vertical transistor 80 may be a cathode for acting as the first emitter 23 of the vertical organic light emitting transistor 20. The fifth electrode 81 may be made of calcium/aluminum, lithium fluoride/aluminum, cesium fluoride/aluminum, barium/aluminum, or a combination thereof. The third organic layer 82 may comprise an ETL that is stacked on the fifth electrode 81. The insulation layer 83 may be first stacked on the ETL, and then the sixth electrode 84 may be stacked on the insulation layer 83. The sixth electrode 84 may be a base for acting as the first base 22 of the vertical organic light emitting transistor 20. The fourth organic layer 91 of the second organic light emitting diode 90 may comprise an EML (EMission Layer), and the seventh electrode 92 may be an anode for acting as the first collector 21 of the vertical organic light emitting transistor 20, wherein the seventh electrode 92 may be a transparent electrode such as ITO (Indium Tin Oxide) so that the light emitted from the second organic light emitting diode 90 is allowed to emit upward through the seventh electrode 92. Alternatively, the seventh electrode 92 may be made of gold, platinum, molybdenum oxide/aluminum, PEDOT/molybdenum oxide/aluminum, or a combination thereof.

Similarly, when the insulation layer 83 and the sixth electrode 84 are in proper thicknesses, the electrons injected from the fifth electrode 81 are allowed to tunnel through the insulation layer 83 and then pass through the sixth electrode 84 ballistically. By controlling the current of the sixth electrode 84, the electron can pass the sixth electrode 84 and get into the fourth organic layer 91 without collision and contribute to the base current. After passing through the sixth electrode 84 and reaching the fourth organic layer 91, the electrons are recombined with the electron holes injected from the seventh electrode 92 at the fourth organic layer 91 and thereby the light emits from the EML of the fourth organic layer 91. Consequently, the light-emitting intensity of the second organic light emitting diode 90 can be controlled by using a current of the sixth electrode 84 to modulate an amount the electrons entering the second organic light emitting diode 90.

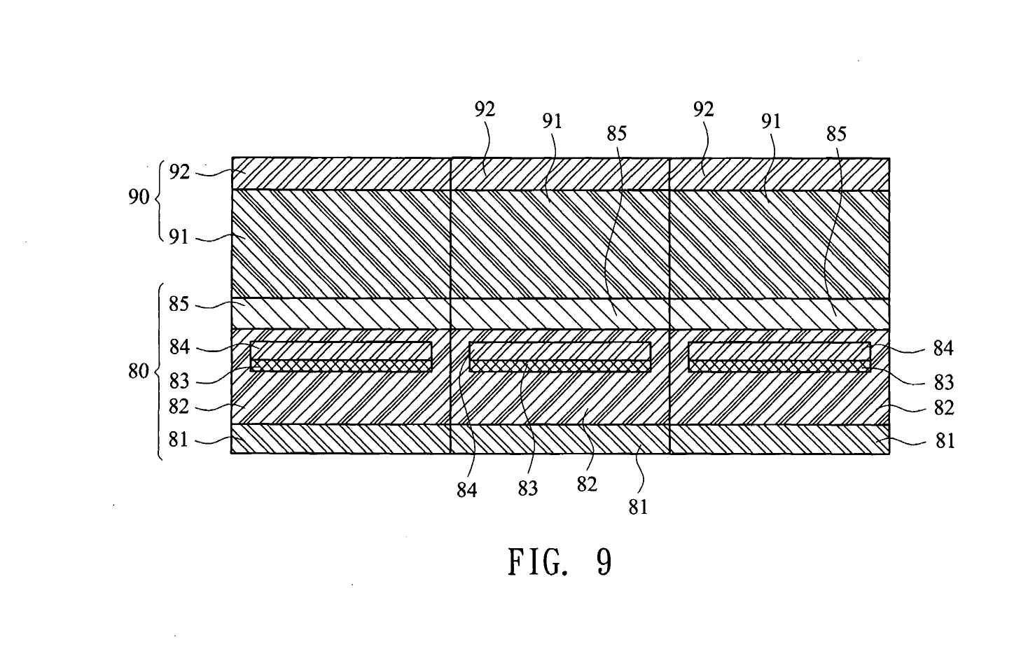

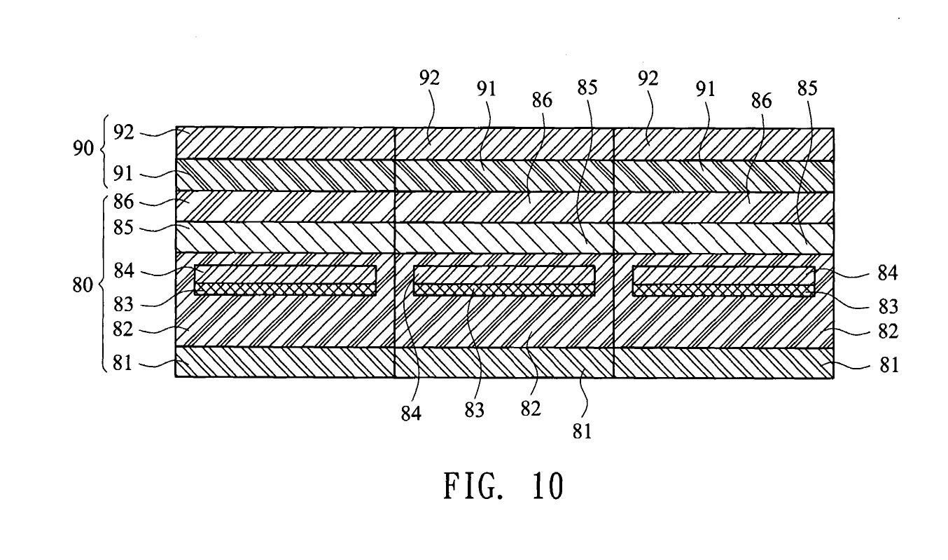

FIG. 9 is a sectional view of the passive matrix organic light emitting diode display device according to a third aspect of the present invention. Therein, a fifth organic layer 85 is additionally provided between the sixth electrode 84 of the second vertical transistor 80 and the fourth organic layer 91 of the second organic light emitting diode 90 of the second aspect as shown in FIG. 8. The fifth organic layer 85 may be an ETL, an EBL, and HTL or an HBL so as to reduce energy barrier difference between the layers and in turn enhance luminescence efficiency of the second organic light emitting diode 90.

FIG. 10 provides a sectional view of the passive matrix organic light emitting diode display device according to a fourth aspect of the present invention wherein an eighth electrode 86 is further added to the third aspect of the present invention as shown in FIG. 9. The fifth organic layer 85 is stacked on the sixth electrode 84 and then the eighth electrode 86 is stacked on the fifth organic layer 85 so that the eighth electrode 86 is sandwiched between the fourth organic layer 91 and the fifth organic layer 85. The eighth electrode 86 may be made of a metal, such as aluminum or silver, or the eighth electrode 86 may be formed as a multi-layer structure comprising a highly conductive macromolecular material such as PEDOT or a metal and other materials. Such multi-layer structure may be made of aluminum/molybdenum oxide, aluminum/molybdenum oxide/PEDOT, gold/PEDOT and so on.

As mentioned previously, when the fifth electrode 81 of the second vertical transistor 80 is the anode acting as the first emitter 23 of the vertical organic light emitting transistor 20, and the sixth electrode 84 is the base acting as the first base 22 of the vertical organic light emitting transistor 20 while the seventh electrode 92 is the cathode acting as the first collector 21 of the vertical organic light emitting transistor 20, the eighth electrode 86 is properly an anode. Otherwise, when the fifth electrode 81 of the second vertical transistor 80 is the cathode acting as the first emitter 23 of the vertical organic light emitting transistor 20, and the sixth electrode 84 is the base acting as the first base 22 of the vertical organic light emitting transistor 20 while the seventh electrode 92 is the anode acting as the first collector 21 of the vertical organic light emitting transistor 20, the eighth electrode 86 is properly a cathode.

For meeting various needs in design, the vertical organic light emitting transistor 20 may be uprighted on either end so that the vertical organic light emitting transistor 20 can emit light upward or downward. Alternatively, a proper material may be used to produce the vertical organic light emitting transistor 20 so that the electrodes at the both ends thereof can be light-previous so that the vertical organic light emitting transistor 20 can emit light at its both ends simultaneously. Furthermore, by constructing the vertical organic light emitting transistors 20 into a passive matrix organic light emitting diode display device, an aperture ratio of each pixel unit in the display device can be increased and consequently an active area as well as a luminance of the display device can be enhanced. Meanwhile, an area of each said pixel unit can be downsized and an image definition of the passive matrix organic light emitting diode display device can be ameliorated.

Although the particular embodiments of the invention have been described in detail for purposes of illustration, it will be understood by one of ordinary skill in the art that numerous variations will be possible to the disclosed embodiments without going outside the scope of the invention as disclosed in the claims.

What is claimed is:

1. A passive matrix organic light emitting diode display device, comprising a plurality of vertical organic light emitting transistors, each having a first collector, a first grid/base, and a first emitter, wherein the first collectors are electrically connected and arranged parallelly to form a plurality of first scan units, and the first grids/bases are electrically connected and arranged parallelly to form a plurality of second scan units, while the first emitters are electrically connected and arranged parallelly to form a plurality of third scan units in which the first scan units and the second scan units are crisscrossed while the second scan units and the third scan units are crisscrossed.

2. The organic light emitting diode display device as claimed in claim 1, wherein the third scan units are integrated into a common electrode.

3. The organic light emitting diode display device as claimed in claim 1, wherein the vertical organic light emitting transistor has a first vertical transistor, which comprises a first electrode, a first organic layer stacked on the first electrode, and a second electrode located in the first organic layer, and a first organic light emitting diode, which comprises a second organic layer perpendicularly stacked on the first vertical transistor, and a third electrode stacked on the second organic layer.

4. The organic light emitting diode display device as claimed in claim 3, wherein the first electrode is an anode acting as the first emitter, and the second electrode is a grid acting as the first grid, while the third electrode is a cathode acting as the first collector.

5. The organic light emitting diode display device as claimed in claim 3, wherein the first electrode is a cathode acting as the first emitter, and the second electrode is a grid acting as the first grid, while the third electrode is an anode acting as the first collector.

6. The organic light emitting diode display device as claimed in claim 3, further comprising a fourth electrode, which is sandwiched between the first organic layer and the second organic layer.

7. The organic light emitting diode display device as claimed in claim 6, wherein the first electrode is an anode acting as the first emitter, and the second electrode is a grid acting as the first grid, while the third electrode is a cathode acting as the first collector and the fourth electrode is an anode.

8. The organic light emitting diode display device as claimed in claim 6, wherein the first electrode is a cathode acting as the first emitter, and the second electrode is a grid acting as the first grid, while the third electrode is an anode acting as the first collector and the fourth electrode is a cathode.

9. The organic light emitting diode display device as claimed in claim 1, wherein the vertical organic light emitting transistor comprises a second vertical transistor, which has a fifth electrode, a third organic layer stacked on the fifth electrode, an insulation layer stacked on the third organic layer, and a sixth electrode stacked on the insulation layer, and a second organic light emitting diode, which has a fourth organic layer perpendicularly stacked on the second vertical transistor and a seventh electrode stacked on the fourth organic layer.

10. The organic light emitting diode display device as claimed in claim 9, wherein the fifth electrode is an anode acting as the first emitter, and the sixth electrode is a base acting as the first base while the seventh electrode is a cathode acting as the first collector.

11. The organic light emitting diode display device as claimed in claim 9, wherein the fifth electrode is a cathode acting as the first emitter, and the sixth electrode is a base acting as the first base while the seventh electrode is an anode acting as the first collector.

12. The organic light emitting diode display device as claimed in claim 9, wherein the second vertical transistor further comprises a fifth organic layer, which is sandwiched between the sixth electrode and the fourth organic layer.

13. The organic light emitting diode display device as claimed in claim 9, wherein the second vertical transistor further comprises a fifth organic layer and an eighth electrode, in which the fifth organic layer is sandwiched between the sixth electrode and the eighth electrode while the eighth electrode is sandwiched between the fifth organic layer and the fourth organic layer.

14. The organic light emitting diode display device as claimed in claim 13, wherein the fifth electrode is an anode acting as the first emitter, and the sixth electrode is a base acting as the first base, while the seventh electrode is a cathode acting as the first collector and the eighth electrode is an anode.

15. The organic light emitting diode display device as claimed in claim 13, wherein the fifth electrode is a cathode acting as the first emitter, and the sixth electrode is a base acting as the first base, while the seventh electrode is an anode acting as the first collector and the eighth electrode is a cathode.
